(19) United States
(12) Patent Application Publication
(10) Pub. No.: US 2026/0079310 A1
(43) Pub. Date: Mar. 19, 2026

(54) CHIP STRUCTURE AND SEMICONDUCTOR PACKAGE

(71) Applicant: SAMSUNG ELECTRONICS CO., LTD., Suwon-si (KR)

(72) Inventors: Jing Cheng Lin, Suwon-si (KR); Jung Hua Chang, Suwon-si (KR)

(73) Assignee: SAMSUNG ELECTRONICS CO., LTD., Suwon-si (KR)

(21) Appl. No.: 19/279,528

(22) Filed: Jul. 24, 2025

(30) Foreign Application Priority Data
Sep. 13, 2024 (KR) 10-2024-0126189

(51) Int. Cl. G02B 6/42; H01L 23/00; H01L 25/16

(52) U.S. Cl. CPC G02B 6/4214; H10W 90/00; H10W 90/792

(57) ABSTRACT

Provided is a chip structure, including a photonic integrated circuit chip including a grating coupler, an electronic integrated circuit chip on the photonic integrated circuit chip, an optical block on the photonic integrated circuit chip and spaced apart from the electronic integrated circuit chip in a horizontal direction, the optical block including a micro lens which is convex toward the photonic integrated circuit chip in a vertical direction, and an insulating layer on the electronic integrated circuit chip, the optical block, and the photonic integrated circuit chip, wherein the micro lens overlaps the grating coupler in the vertical direction.

### CROSS-REFERENCE TO RELATED APPLICATION

This application claims priority to Korean Patent Application No. 10-2024-0126189, filed on Sep. 13, 2024, in the Korean Intellectual Property Office, the disclosure of which is incorporated by reference herein in its entirety.

### BACKGROUND

Embodiments of the present disclosure relate to a chip structure and a semiconductor package.

With the rapid development of the electronics industry and increased demands of users, electronic devices are becoming increasingly smaller and lighter. Accordingly, semiconductor packages used therein are also becoming smaller and lighter. Thus, higher integration of semiconductor devices is required.

Accordingly, semiconductor packages in which various integrated circuits, such as, memory chips or logic chips, are mounted on a package substrate have been developed to provide multiple functions. In particular, in an environment where data traffic is increasing in recent data centers and communication infrastructure, research on semiconductor packages including photonic integrated circuits has advanced.

### SUMMARY

One or more embodiments provide a chip structure and a semiconductor package including a highly efficient optical engine.

According to an aspect of one or more embodiments, there is provided a chip structure, including a photonic integrated circuit chip including a grating coupler, an electronic integrated circuit chip on the photonic integrated circuit chip, an optical block on the photonic integrated circuit chip and spaced apart from the electronic integrated circuit chip in a horizontal direction, the optical block including a micro lens which is convex toward the photonic integrated circuit chip in a vertical direction, and an insulating layer on the electronic integrated circuit chip, the optical block, and the photonic integrated circuit chip, wherein the micro lens overlaps the grating coupler in the vertical direction.

According to another aspect of one or more embodiments, there is provided a semiconductor package, including an interposer substrate, a first semiconductor chip, a second semiconductor chip, and an electronic integrated circuit chip on the interposer substrate, the first semiconductor chip, the second semiconductor chip, and the electronic integrated circuit chip being spaced apart from each other in a horizontal direction, an optical block on the interposer substrate and spaced apart from the electronic integrated circuit chip in the horizontal direction, the optical block including a micro lens which is convex in a direction toward the interposer substrate, an optical adhesive layer between the optical block and the interposer substrate, and a molding member on the first semiconductor chip, the second semiconductor chip, the electronic integrated circuit chip, and the optical block, wherein the interposer substrate is configured to electrically connect the electronic integrated circuit chip to the second semiconductor chip, the interposer substrate including a grating coupler that overlaps the micro lens in a vertical direction.

According to still another aspect of one or more embodiments, there is provided a semiconductor package, including a package substrate, an interposer substrate on the package substrate, a first semiconductor chip and a second semiconductor chip on the interposer substrate, the first semiconductor chip and the second semiconductor chip being spaced apart from each other in a horizontal direction, an electronic integrated circuit chip on the interposer substrate and spaced apart from the first semiconductor chip and the second semiconductor chip in the horizontal direction, an optical block spaced apart from the electronic integrated circuit chip in the horizontal direction, the optical block including a plurality of micro lenses at a bottom surface of the optical block and are convex toward the interposer substrate, a plurality of grating couplers between the optical block and the package substrate, the plurality of grating couplers corresponding to the plurality of micro lenses, respectively, and an optical adhesive layer between the plurality of grating couplers and the optical block, wherein the plurality of grating couplers and the plurality of micro lenses are respectively provided in the horizontal direction.

### BRIEF DESCRIPTION OF DRAWINGS

Embodiments will be more clearly understood from the following detailed description taken in conjunction with the accompanying drawings in which:

FIG. 1 is a schematic plan view of a semiconductor package according to one or more embodiments;

FIG. 2 is a cross-sectional view of the semiconductor package taken along line A1-A1′ in FIG. 1;

FIG. 3 is a schematic enlarged view of portion I in FIG. 2;

FIG. 4 is a schematic enlarged view of portion II in FIG. 3;

FIG. 5 is a schematic plan view showing a positional relationship between a micro lens and a grating coupler;

FIG. 6 is a schematic cross-sectional view of a semiconductor package according to one or more embodiments; and

FIGS. 7A, 7B, 7C, 7D, 7E, 7F, 7G, and 7H are cross-sectional views illustrating a method of manufacturing the semiconductor package of FIG. 2.

### DETAILED DESCRIPTION

Hereinafter, embodiments are described in detail with reference to the accompanying drawing. The same reference numerals are used for the same components in the drawings and duplicate descriptions thereof are omitted.

In the following embodiments, terms, such as first and second, are used not in a limiting sense but for the purpose of distinguishing one component from another component.

In the following embodiments, singular terms include plural terms unless the context clearly dictates otherwise.

In the drawings, the sizes of components may be exaggerated or reduced for convenience of explanation. For example, the size and thickness of each component shown in the drawings are arbitrarily shown for convenience of explanation. Thus, the inventive concept is not necessarily limited to what is shown.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

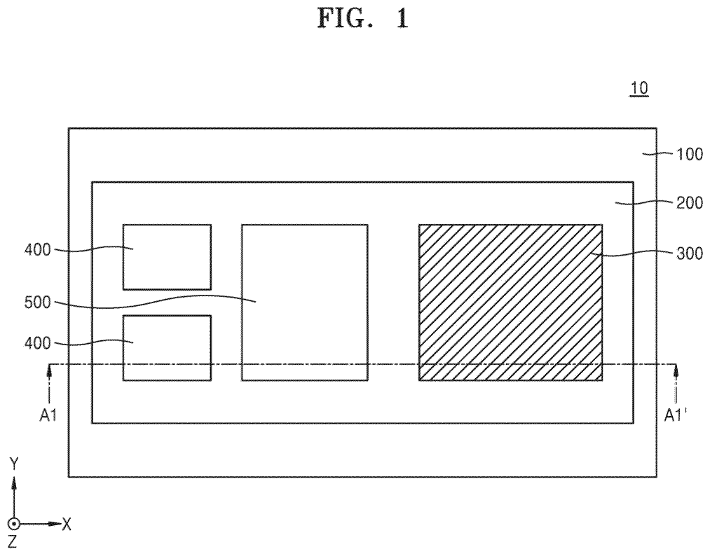

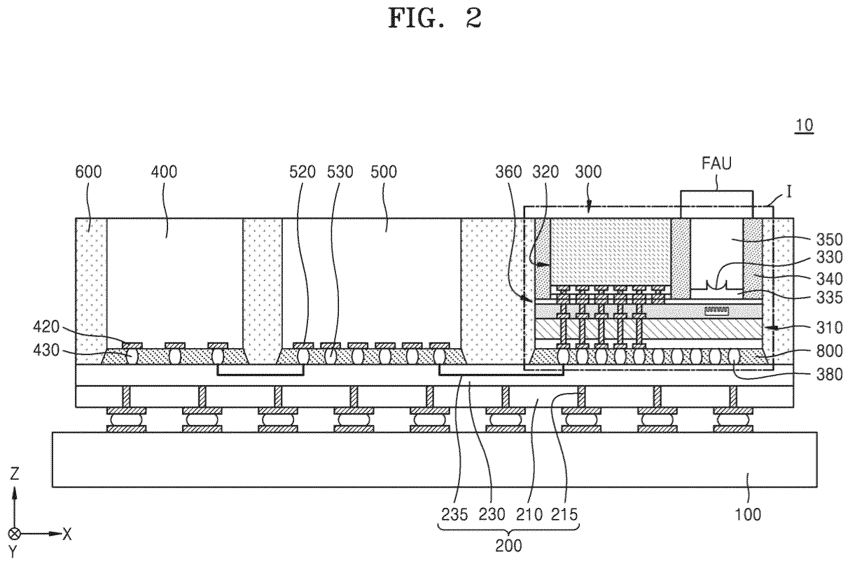

FIG. 1 is a schematic plan view of a semiconductor package according to one or more embodiments and FIG. 2 is a cross-sectional view of the semiconductor package taken along line A1-A1′ in FIG. 1.

Referring to FIGS. 1 and 2, a semiconductor package 10 may include a package substrate 100, an interposer substrate 200, a chip structure 300, first semiconductor chips 400, and a second semiconductor chip 500. According to one or more embodiments, the semiconductor package 10 may communicate with an external device through an optical signal. In one or more embodiments, the semiconductor package 10 may include a silicon photonics engine.

In the following drawings, an X-axis direction and a Y-axis direction may represent directions parallel to the surface of the package substrate 100 and may be understood as directions perpendicular to each other. A Z-axis direction may represent a direction perpendicular to the upper or lower surface of the package substrate 100, that is, a direction perpendicular to the X-Y plane. In addition, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The package substrate 100 may include a substrate on which the interposer substrate 200 is mounted. In one or more embodiments, the package substrate 100 may include a motherboard on which various types of semiconductor chips and packages are mounted. Additionally, in one or more embodiments, the package substrate 100 may include a substrate that operates as an intermediate bridge, receiving electrical signals from the interposer substrate 200 and transmitting the electric signals to an external device.

According to one or more embodiments, the package substrate 100 may include a printed circuit board (PCB) that includes wiring patterns and an insulating layer provided on or surrounding the wiring patterns therein. The wiring patterns may include, for example, copper (Cu), nickel (Ni), stainless steel, or beryllium copper (BeCu). The insulating layer may include at least one material selected from phenol resin, epoxy resin, and polyimide. For example, the insulating layer may include at least one of, for example, flame retardant 4 (FR-4), tetra-functional epoxy, polyphenylene ether, epoxy/polyphenylene oxide, bismaleimide triazine (BT), Thermount, cyanate ester, polyimide, and liquid crystal polymer.

The interposer substrate 200 may be mounted on the package substrate 100. The interposer substrate 200 may include silicon and may form an electrical connection between the first semiconductor chip 400, the second semiconductor chip 500, and the chip structure 300, each mounted on the interposer substrate 200. For example, the interposer substrate 200 may operate as a connection passage for an electrical connection between the first semiconductor chip 400, the second semiconductor chip 500, and the chip structure 300.

According to one or more embodiments, when the first semiconductor chip 400, the second semiconductor chip 500, and the chip structure 300 are of different types of chips or chip structures, the first semiconductor chip 400, the second semiconductor chip 500, and the chip structure 300 may exchange electrical signals with each other through the interposer substrate 200.

The interposer substrate 200 may include a wiring layer 230 and a body layer 210. The wiring layer 230 may be located on the upper surface of the body layer 210. Through vias 215 may be formed in the body layer 210. The through vias 215 may pass through the body layer 210 in the vertical direction Z. According to one or more embodiments, the through vias 215 may include a through silicon via (TSV). The wiring layer 230 may include wiring patterns 235. The wiring patterns 235 may electrically connect the first semiconductor chip 400, second semiconductor chip 500, and chip structure 300 to each other or may form an electrical connection between the first semiconductor chip 400 and the through vias 215, between the second semiconductor chip 500 and the through vias 215, and between the chip structure 300 and the through vias 215. The through vias 215 may be electrically connected to the package substrate 100 through pads and bumps formed on the lower surface of the body layer 210.

According to one or more embodiments, the interposer substrate 200 may be electrically connected to the chip structure 300 through first bumps 380, may be electrically connected to the first semiconductor chip 400 through second bumps 430, and may be electrically connected to the second semiconductor chip 500 through third bumps 530.

The first semiconductor chip 400, the second semiconductor chip 500, and the chip structure 300 may be mounted on the interposer substrate 200. The first semiconductor chip 400 may be mounted on the interposer substrate 200 through the chip pads 420 and the second bumps 430, such as, for example, micro bumps, by a flip chip method. According to one or more embodiments, an underfill material layer 800 provided on or surrounding the second bumps 430 may be placed between the first semiconductor chip 400 and the interposer substrate 200. The underfill material layer 800 may include, for example, an epoxy resin formed by a capillary underfill method. However, embodiments are not limited thereto, and, for example, a molding member 600 may directly fill the gap between the first semiconductor chip 400 and the interposer substrate 200 through a molded underfill process. In this case, the underfill material layer 800 may be omitted.

According to one or more embodiments, the first semiconductor chip 400 may include a memory chip. The memory chip may include, for example, a volatile memory chip, such as dynamic random-access memory (DRAM) or static random-access memory (SRAM), or a non-volatile memory chip, such as phase-change random-access memory (PRAM), magnetoresistive random-access memory (MRAM), ferroelectric random-access memory (FeRAM), or resistive random-access memory (RRAM). Additionally, according to one or more embodiments, the first semiconductor chip 400 may include, for example, a high bandwidth memory (HBM) package or a wire bonding memory package in which a plurality of memory chips are stacked in the vertical direction Z.

The second semiconductor chip 500 may be mounted on the interposer substrate 200 while being spaced apart from the first semiconductor chip 400 in the horizontal direction (e.g., X and/or Y direction). The second semiconductor chip 500 may be mounted on the interposer substrate 200 through chip pads 520 and third bumps 530, such as, for example, micro bumps, by a flip chip method. According to one or more embodiments, the underfill material layer 800 provided on or surrounding the third bumps 530 may be placed between the second semiconductor chip 500 and the interposer substrate 200. The underfill material layer 800 may include, for example, an epoxy resin formed by a capillary underfill method. However, embodiments are not limited thereto, and for example, the molding member 600 may directly fill the gap between the second semiconductor chip 500 and the interposer substrate 200 through a molded underfill process. In this case, the underfill material layer 800 may be omitted.

According to one or more embodiments, the second semiconductor chip 500 may include, for example, a logic chip. The logic chip may include, for example, a microprocessor, such as a central processing unit (CPU), a graphics processing unit (GPU), or an application processor (AP), an analog device, or a digital signal processor.

However, the first semiconductor chip 400 is not limited to the memory chip and the second semiconductor chip 500 is not limited to the logical chip. In one or more embodiments, the first semiconductor chip 400 and the second semiconductor chip 500 may each include the memory chip or the logic chip. The first semiconductor chip 400 may include the logic chip and the second semiconductor chip 500 may include the memory chip.

The chip structure 300 may be mounted on the interposer substrate 200 while being spaced apart from the first semiconductor chip 400 and the second semiconductor chip 500 in the horizontal direction (e.g., X and/or Y direction). In one or more embodiments, the chip structure 300 may be spaced apart from the first semiconductor chip 400 in the first horizontal direction (e.g., X direction) with the second semiconductor chip 500 in between. The chip structure 300 may be mounted on the interposer substrate 200 through first bumps 380, such as, for example, micro bumps, by a flip chip method. According to one or more embodiments, the underfill material layer 800 provided on or surrounding the first bumps 380 may be placed between the chip structure 300 and the interposer substrate 200. The underfill material layer 800 may include, for example, an epoxy resin formed by a capillary underfill method. However, embodiments are not limited thereto, and for example, the molding member 600 may directly fill the gap between the chip structure 300 and the interposer substrate 200 through a molded underfill process. In this case, the underfill material layer 800 may be omitted.

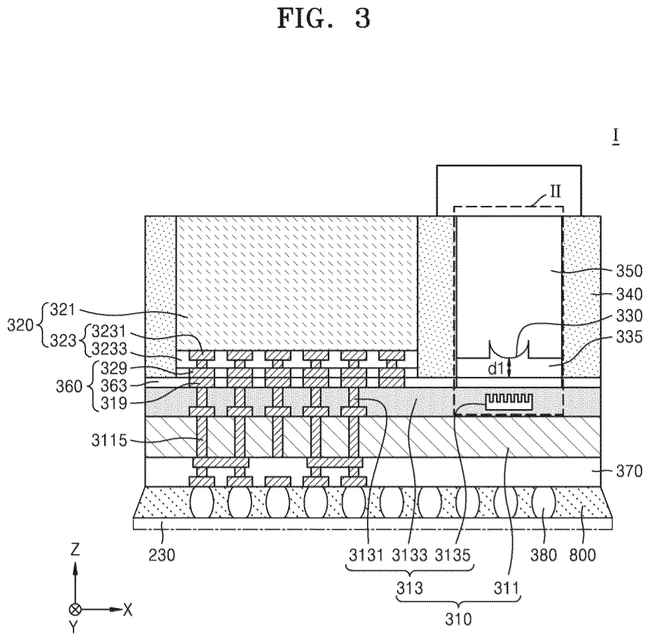

The semiconductor package 10 may communicate with an external device using the optical signal through the chip structure 300. The chip structure 300 may receive the optical signal from the external device, convert the received optical signal into an electrical signal, and input the converted electrical signal to the second semiconductor chip 500 through the interposer substrate 200. The chip structure 300 may be an optical engine. The chip structure 300 may include a photonic integrated circuit (PIC) chip 310, an electronic integrated circuit (EIC) chip 320, and an optical block 350. The chip structure 300 may be described in detail below with reference to FIG. 3.

The molding member 600 may be provided on or surround the first semiconductor chip 400, the second semiconductor chip 500, and the chip structure 300 on the upper surface of the interposer substrate 200. In one or more embodiments, the molding member 600 may be provided on or cover the side surfaces of each of the first semiconductor chip 400, the second semiconductor chip 500, and the chip structure 300 and may not cover the upper surface of each of the first semiconductor chip 400, the second semiconductor chip 500, and the chip structure 300. The upper surface of the molding member 600 may be coplanar with the upper surface of each of the first semiconductor chip 400, the second semiconductor chip 500, and the chip structure 300. In the same sense, the upper surface of the molding member 600 may have the same vertical level as the upper surface of each of the first semiconductor chip 400, the second semiconductor chip 500, and the chip structure 300. The upper surface of the molding member 600 may be coplanar with the upper surface of the EIC chip 320 and the upper surface of the optical block 350.

For convenience of explanation, the molding member 600 is not shown in FIG. 1 but is shown only in FIG. 2. In FIG. 1, the molding member 600 may be provided on or surround the first semiconductor chip 400, the second semiconductor chip 500, and the chip structure 300 on the interposer substrate 200 or may be provided on or surround the interposer substrate 200, the first semiconductor chip 400, the second semiconductor chip 500, and the chip structure 300 on the package substrate 100.

According to one or more embodiments, the molding member 600 may include a thermosetting resin, such as, for example, epoxy resin, a thermoplastic resin, such as polyimide, or a resin including a reinforcing material, such as an inorganic filler, specifically Ajinomoto build-up film (ABF), FR-4, BT, and the like, but is not limited thereto. The molding member 600 may include a molding material, such as, for example, EMC, or a photosensitive material, such as a photoimageable encapsulant (PIE). In one or more embodiments, a portion of the molding member 390 may include an insulating material, such as, for example, a silicon oxide film, a silicon nitride film, or a silicon oxynitride film.

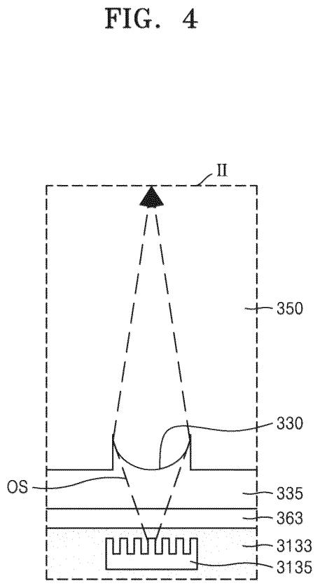

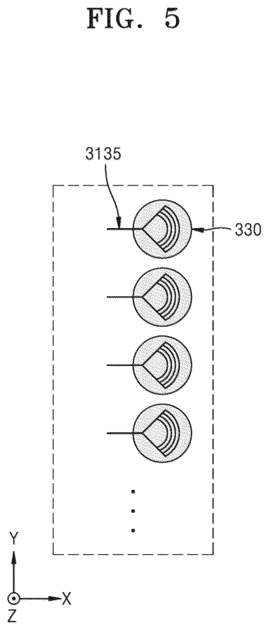

FIG. 3 is a schematic enlarged view of portion I in FIG. 2, FIG. 4 is a schematic enlarged view of portion II in FIG. 3, and FIG. 5 is a schematic plan view showing the positional relationship between a micro lens and a grating coupler.

Referring to FIGS. 3 and 4, the chip structure 300 may include a redistribution structure 370, the PIC chip 310, the EIC chip 320, the optical block 350, and an insulating layer 340.

The redistribution structure 370 may include a structure that electrically connects the PIC chip 310 to the interposer substrate 200 (see FIG. 2). The redistribution structure 370 may be provided on the wiring layer 230 of the interposer substrate 200. According to one or more embodiments, the redistribution structure 370 may include a redistribution insulating layer and redistribution patterns. The redistribution insulating layer may be stacked in the vertical direction Z and the redistribution patterns may be provided within the redistribution insulating layer. The redistribution insulating layer may be formed from, for example, photo imageable dielectric (PID) or photosensitive polyimide (PSPI). The redistribution patterns may be formed from a metal, such as, for example, Cu, aluminum (Al), tungsten (W), titanium (Ti), tantalum (Ta), indium (In), molybdenum (Mo), manganese (Mn), cobalt (Co), tin (Sn), Ni, magnesium (Mg), rhenium (Re), beryllium (Be), gallium (Ga), and ruthenium (Ru), or a metal alloy. However, embodiments are not limited thereto. In one or more embodiments, the redistribution patterns may be formed by stacking the metal or the metal alloy on a seed layer including Cu, Ti, titanium nitride (TiN), or titanium tungsten (TiW). The PIC chip 310 and the interposer substrate 200 may exchange electrical signals through the redistribution patterns of the redistribution structure 370.

The PIC chip 310 may include a first substrate 311 and a first wiring structure 313. The first substrate 311 may include a semiconductor material, such as, for example, silicon or germanium. According to one or more embodiments, the PIC chip 310 may be mounted on the interposer substrate 200 so that the first substrate 311 faces the interposer substrate 200. The PIC chip 310 may be mounted on the interposer substrate 200 through the first bumps 380 by a flip chip method.

The first wiring structure 313 may include first wiring patterns 3131, a first wiring insulating layer 3133 provided on or surrounding the first wiring patterns 3131, and a grating coupler 3135.

The first wiring patterns 3131 may include a first wiring line extending in the horizontal direction (e.g., X and/or Y) and a first wiring via extending from the first wiring line in the vertical direction Z. The first wiring patterns 3131 may be electrically connected to through vias 3115.

The first wiring insulating layer 3133 may be located on the upper surface of the first substrate 311. In one or more embodiments, the first wiring insulating layer 3133 may be provided as multiple layers. For example, the first wiring insulating layer 3133 may be provided as two layers. In this case, the insulating layer located in the lower layer may be understood as a lower wiring insulating layer and the insulating layer located in the upper layer may be understood as an upper wiring insulating layer. In one or more embodiments, the lower wiring insulating layer may include an oxide layer of, for example, silicon oxide, and the upper wiring insulating layer may include a dielectric layer formed of one or greater layers of, for example, silicon oxide, silicon nitride, or a combination thereof.

A bonding insulating layer 363 and upper pads 319 may be provided on the upper surface of the PIC chip 310. For example, the bonding insulating layer 363 and the upper pads 319 may be located on the upper surface of the first wiring insulating layer 3133. The bonding insulating layer 363 may be provided on or surround the side surfaces of the upper pads 319. The upper surfaces of the upper pads 319 may be exposed from the bonding insulating layer 363 in the vertical direction (for example, Z direction). The upper pads 319 may be electrically connected to the first wiring patterns 3131 and may also be electrically connected to lower pads 329 of the EIC chip 320. A plurality of upper pads 319 may be provided. The plurality of upper pads 319 may be positioned to overlap the EIC chip 320 in the vertical direction Z.

The grating coupler 3135 may be provided within the first wiring insulating layer 3133. According to one or more embodiments, a waveguide and a photonic component may be arranged within the first wiring insulating layer 3133 and the grating coupler 3135 may be located in one area of the waveguide. The waveguide, which includes a patterned silicon layer, may extend in the first horizontal direction (for example, X direction). In one or more embodiments, the waveguide may include a silicon waveguide including silicon and the first wiring insulating layer 3133 may include a buried oxide (BOX) layer. However, embodiments are not limited thereto. The waveguide may be covered by an oxide layer distinct from the first wiring insulating layer 3133. The photonic component may be connected to the waveguide and may convert an optical signal OS into an electrical signal or convert the electrical signal into the optical signal OS. The photonic component may include, for example, a photodetector, a photodiode, and a modulator.

In the process of inputting the optical signal OS to the chip structure 300, the photodetector may detect the optical signal OS input to the PIC chip 310. The PIC chip 310 may detect the optical signal OS input through the photodetector and convert the same into an electrical signal.

In the process of outputting the optical signal OS by the chip structure 300, the EIC chip 320 may transmit the electrical signal to the modulator. The modulator may convert the electrical signal into an optical signal OS by inputting a value corresponding to the electrical signal received by the light emitted by the photodiode.

The grating coupler 3135 may be located on one side of the waveguide. The PIC chip 310 may receive the aggregated optical signal OS from the optical block 350 through the grating coupler 3135 or transmit the optical signal OS to the optical block 350. The grating coupler 3135 may control the direction of the optical signal OS incident through the optical block 350 or the direction of the optical signal OS to be emitted to the optical block 350. For example, the direction of the optical signal OS incident through the optical block 350 may be changed by the grating coupler 3135 so that the optical signal OS moves along the waveguide. As another example, the direction of the optical signal OS moving along the waveguide may be changed by the grating coupler 3135 so that the optical signal OS is emitted to the optical block 350.

Referring to FIGS. 2 to 4, according to one or more embodiments, since the grating coupler 3135 is included in the PIC chip 310 disposed on the interposer substrate 200, the grating coupler 3135 may overlap the first semiconductor chip 400 and the second semiconductor chip 500 in the horizontal direction (for example, X and/or Y direction). The grating coupler 3135 may not overlap the EIC chip 320 in the horizontal direction (for example, X and/or Y direction). For example, the grating coupler 3135 is spaced apart from the EIC chip 320 in the vertical direction (Z direction). The grating coupler 3135 may overlap the optical block 350 in the vertical direction (Z direction).

The EIC chip 320 may be located on the PIC chip 310. The EIC chip 320 may be configured to interconnect the PIC chip 310 to the first semiconductor chip 400 and the second semiconductor chip 500. For example, the EIC chip 320 may convert the electrical signal converted by the PIC chip 310 to match the first semiconductor chip 400 and the second semiconductor chip 500.

In one or more embodiments, the horizontal width of the EIC chip 320 may be less than the horizontal width of the PIC chip 310. A size of the EIC chip 320 may be less than a size of the PIC chip 310.

The EIC chip 320 may include a second substrate 321 and a second wiring structure 323. The second substrate 321 of the EIC chip 320 may include an active surface and an inactive surface opposite to the active surface. The second wiring structure 323 may be formed on the active surface of the second substrate 321. The EIC chip 320 may be placed on the PIC chip 310 so that the active surface of the second substrate 321 faces the PIC chip 310. The second substrate 321 may include a semiconductor material, such as, for example, silicon or germanium.

In one or more embodiments, the EIC chip 320 may include a plurality of individual devices used to interface with the PIC chip 310. The plurality of individual devices of the EIC chip 320 may be located on the active surface of the second substrate 321. For example, the EIC chip 320 may include CMOS drivers, transimpedance amplifiers, and the like, to perform operations, such as controlling high-frequency signaling of the PIC chip 310.

The second wiring structure 323 may include second wiring patterns 3231 and a second wiring insulating layer 3233 provided on or surrounding the second wiring patterns 3231. The second wiring patterns 3231 may include a second wiring line extending in the horizontal direction and a second wiring via extending from the second wiring line in the vertical direction Z. The second wiring patterns 3231 may be electrically connected to the plurality of individual devices and the lower pads 329.

According to one or more embodiments, a bonding layer 360 may be located between the EIC chip 320 and the PIC chip 310. The bonding layer 360 may include the upper pads 319, the lower pads 329, and the bonding insulating layer 363. The upper pads 319 may include pads located on the upper surface of the PIC chip 310. The lower pads 329 may include pads located on the lower surface of the EIC chip 320. The EIC chip 320 and the PIC chip 310 may be electrically connected to each other by the bonding layer 360 located between the EIC chip 320 and the PIC chip 310.

The EIC chip 320 and PIC chip 310 may be bonded by direct bonding. The direct bonding may include, for example, dielectric-to-dielectric bonding, copper-to-copper bonding, and hybrid bonding in which the dielectric-dielectric bonding and metal-to-metal bonding are performed together. The direct bonding may include diffusion bonding in which two interfaces including the same material and facing each other are placed opposite to each other, then brought into contact with each other and heated so that the metal atoms or dielectric materials in contact with each other are integrated through diffusion.

According to one or more embodiments, the bonding layer 360 may be formed when the upper pads 319 of the PIC chip 310 and the lower pads 329 of the EIC chip 320 are diffusion bonded by heat, and the insulating layer provided on or surrounding the upper pads 319 of the PIC chip 310 and the insulating layer provided on or surrounding the lower pads 329 of the EIC chip 32 are diffusion bonded by heat.

The process of bonding the EIC chip 320 with the PIC chip 310 is not limited thereto. The EIC chip 320 and the PIC chip 310 may be electrically connected by connection terminals, such as, for example, solder balls, or adhesive films, such as anisotropic films (ACF) or non-conductive films (NCF).

The optical block 350 may be located above the PIC chip 310. The horizontal width of the optical block 350 may be less than the horizontal width of the PIC chip 310. The optical block 350 may be spaced apart from the EIC chip 320 in the horizontal direction (for example, X and/or Y direction). In one or more embodiments, the optical block 350 may be spaced apart from the upper surface of the PIC chip 310 in the vertical direction Z. The optical block 350 may be spaced apart from the first semiconductor chip 400 and the second semiconductor chip 500 in the horizontal direction (for example, X and/or Y direction).

An optical adhesive layer 335 may be provided on the lower surface of the optical block 350. The optical block 350 may face the bonding insulating layer 363 of the bonding layer 360 with the optical adhesive layer 335 arranged between the optical block 350 and the bonding insulating layer 363. In one or more embodiments, the optical adhesive layer 335 may be in direct contact with the optical block 350 and the bonding insulating layer 363. For example, among the first layer of the bonding insulating layer 363 provided on or surrounding the upper pad 319 and the second layer of the bonding insulating layer 363 provided on or surrounding the lower pad 329, the optical adhesive layer 335 may directly contact the upper surface of the first layer of the bonding insulating layer 363. For example, only the optical adhesive layer 335 and the first layer of the bonding insulating layer 363 may be arranged between the optical block 350 and the first wiring insulating layer 3133 in which the grating coupler 3135 is embedded. Accordingly, by simplifying the composition and structures blocking the optical block 350 and the grating coupler 3135, the efficiency of the optical signal may be improved.

The optical block 350 may be connected to the optical fiber unit FAU. The optical fiber unit FAU may include a unit including a plurality of optical fibers. From the outside, the optical signal OS may enter the optical block 350 through the optical fiber of the optical fiber unit FAU. The optical fiber unit FAU may include a plurality of optical fibers, and depending on the embodiment, these optical fibers may input/output optical signals of different wavelengths. In one or more embodiments, the optical fiber may input/output the optical signals with multiple wavelengths. For example, the optical signal emitted by the optical fiber may have multiple peak wavelengths. A first end of the optical block 350 may be connected to the optical fiber unit FAU, and a second end opposite to the first end may be in contact with the optical adhesive layer 335.

The optical block 350 may include a main body having a constant refractive index. For example, the material of the main body of the optical block 350 may include silicon, glass, or polymer. Since the main body of the optical block 350 has a constant refractive index, light reflection that occurs between two materials with different refractive indices may be reduced while the optical signal passes through the main body of the optical block 350. As greater than 98% of an optical path is formed in the optical block 350, optical loss due to light reflection may be reduced.

The optical block 350 may be located above the grating coupler 3135 of the PIC chip 310. Inside the optical block 350, the optical path through which an external optical signal OS is transmitted to the PIC chip 310 may be formed. In one or more embodiments, the optical block 350 may have a thickness of about 600 μm to about 800 μm.

Light scattering may occur depending on the distance between the grating coupler 3135 and the optical fiber unit FAU. The light coming from the grating coupler 3135 may not be focused before the light reaches the optical fiber unit FAU, thereby reducing the coupling efficiency. The chip structure 300 and the semiconductor package 10, according to one or more embodiments, may improve the coupling efficiency by including a micro lens 330 arranged at an appropriate location.

The optical block 350 may include the micro lens 330. In one or more embodiments, the micro lens 330 may be formed through a nano-imprint process. For example, after manufacturing a mold with a micro lens pattern engraved thereon, a polymer or photosensitive resist may coat the surface of a substrate including a material, such as glass. Afterwards, the shape of the micro lens may be transferred by pressing the mold with the micro lens pattern engraved thereon on the substrate, and processes, such as annealing, washing, and coating, may be performed to produce the optical block 350 including the micro lens 330.

The micro lens 330 may be located below (or on the lower surface) of the optical block 350. For example, the micro lens 330 may be located on one side of the optical block 350 adjacent to the PIC chip 310. The micro lens 330 may overlap at least one of the bonding layer 360 and the EIC chip 320 in the horizontal direction (for example, X and/or Y direction). The micro lens 330 may have a vertical level that overlaps the first semiconductor chip 400 and the second semiconductor chip 500 in the horizontal direction (for example, X and/or Y direction). For example, at least a portion of the micro lens 330 may overlap the first semiconductor chip 400 and the second semiconductor chip 500 in the horizontal direction (for example, X and/or Y direction).

Referring to FIGS. 3 and 4, the micro lens 330 may be convex downward. For example, the micro lens 330 may be convex in a direction toward the PIC chip 310 and/or the interposer substrate 200.

The micro lens 330 may overlap the grating coupler 3135 in the vertical direction (Z direction). In one or more embodiments, the distance d1 between the micro lens 330 and the upper surface of the PIC chip 310 may be 100 μm or less or 50 μm or less. The distance d1 between the micro lens 330 and the upper surface of the PIC chip 310 may refer to a distance between the point closest to the PIC chip 310 on the convex surface of the micro lens 330 and the upper surface of the PIC chip 310. When the distance d1 between the micro lens 330 and the upper surface of the PIC chip 310 is greater than or equal to 100 μm, the light coming from the grating coupler 3135 has already been emitted and may be difficult to focus through the micro lens 330. The chip structure 300 and the semiconductor package 10, according to one or more embodiments, may improve the coupling efficiency by including the micro lens 330 arranged at an appropriate location, thereby implementing a highly efficient optical engine.

Referring to FIG. 5, a plurality of micro lenses 330 and a plurality of grating couplers 3135 included in the chip structure and the semiconductor package, according to one or more embodiments, may be provided. The chip structure and the semiconductor package, according to one or more embodiments, may include the plurality of micro lenses 330 and the plurality of grating couplers 3135. For example, the micro lenses 330 and the grating couplers 3135 may be provided as an array. In one or more embodiments, the plurality of micro lenses 330 may be arranged in the horizontal direction (for example, X and/or Y direction). The plurality of grating couplers 3135 may be arranged in the horizontal direction (for example, X and/or Y direction).

The plurality of micro lenses 330 may correspond one-to-one with the plurality of grating couplers 3135. The plurality of micro lenses 330 may correspond to the plurality of grating couplers 3135, respectively. For example, each of the plurality of micro lenses 330 may overlap the plurality of grating couplers 3135, respectively, in the vertical direction (Z direction). For example, when the plurality of grating couplers 3135 have a 1×20 array or a 2×20 array on a plane, the plurality of micro lenses 330 may also have a 1×20 array or a 2×20 array corresponding thereto. According to one or more embodiments, one of the plurality of grating couplers 3135 overlapping one of the plurality of micro lenses 330 may not overlap another one of the plurality of micro lenses 330 in the vertical direction (Z direction). For example, one of the plurality of grating couplers 3135 overlapping one of the plurality of micro lenses 330 may be spaced apart from another one of the plurality of micro lenses 330 in the horizontal direction (X and/or Y direction). Thus, the light may be focused on the center of the grating coupler 3135.

The optical signal OS may be irradiated (emitted) by the micro lens 330 as shown in FIG. 4. The optical signal OS irradiated (emitted) by the micro lens 330 may be refracted and converged by the curvature of the micro lens 330. Since the micro lens 330 has a downward convex shape, the optical signal OS irradiated (emitted) by the micro lens 330 may be converged to one point. The optical signal OS may be irradiated (emitted) by the micro lens 330 of the optical block 350, may pass through the inside of the optical block 350, and may be transmitted to the optical fiber unit FAU.

In the chip structure 300 according to one or more embodiments, the micro lens 330 is formed in the optical block 350 through a nano-imprint process, there is no need to provide a new micro lens within the chip structure 300. In addition, since the upper surface of the optical block 350 is not covered by the molding member 600, the optical block 350 may function as a heat dissipation member. Thus, the heat dissipation characteristics of the chip structure 300 and the semiconductor package 10 may be improved.

Referring again to FIG. 3, the insulating layer 340 may be provided on or to surround the EIC chip 320 and the optical block 350. The insulating layer 340 may include silicon oxide (SiO₂). The insulating layer 340 may be formed by a plasma-enhanced chemical vapor deposition (PECVD) process. According to one or more embodiments, the upper surface of the insulating layer 340 may be coplanar with the upper surface of the EIC chip 320 and the upper surface of the optical block 350. In the same sense, the upper surface of the insulating layer 340 may be positioned at the same vertical level as the upper surface of the EIC chip 320 and the upper surface of the optical block 350.

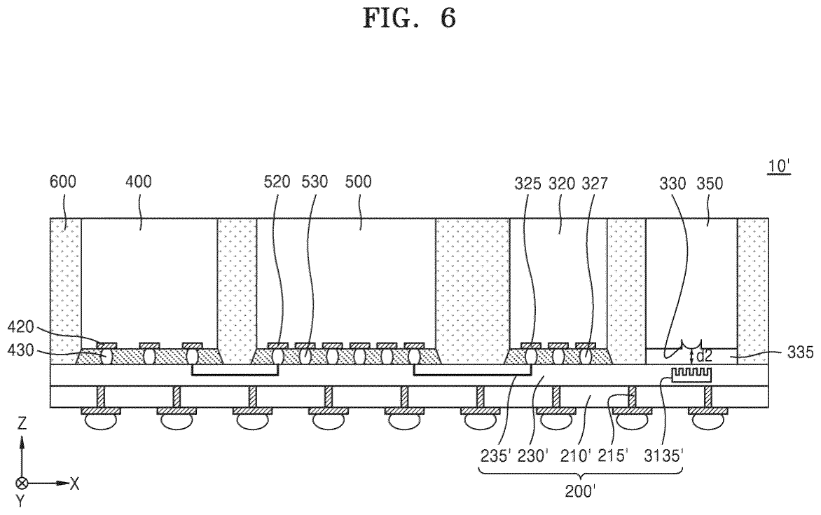

FIG. 6 is a schematic cross-sectional view of a semiconductor package 10′ according to one or more embodiments. In FIG. 6, the same reference numbers as in FIGS. 2 and 3 indicate the same or similar components. Thus, redundant description thereof may be omitted, and the description may focus on the differences.

Referring to FIG. 6, the interposer substrate 200′ of the semiconductor package 10′ according to one or more embodiments may include a photonic interposer substrate. According to one or more embodiments, a first semiconductor chip 400, a second semiconductor chip 500, an EIC chip 320, and an optical block 350 may be placed on the interposer substrate 200′. The first semiconductor chip 400, the second semiconductor chip 500, the EIC chip 320, and the optical block 350 may be spaced apart from each other in the horizontal direction (for example, X and/or Y direction).

The interposer substrate 200′ may electrically connect the first semiconductor chip 400, the second semiconductor chip 500, and the EIC chip 320 to each other, each mounted on the interposer substrate 200′. For example, the interposer substrate 200′ may function as a connection passage for electrical connection between the first semiconductor chip 400, the second semiconductor chip 500, and the EIC chip 320. According to one or more embodiments, when the first semiconductor chip 400, the second semiconductor chip 500, and the EIC chip 320 are of different types of chips or chip structures, the first semiconductor chip 400, the second semiconductor chip 500, and the EIC chip 320 may exchange electrical signals with each other through the interposer substrate 200′.

According to one or more embodiments, unlike the embodiment of FIG. 2, the EIC chip 320 may be mounted on the interposer substrate 200′ through fourth bumps 327 and chip pads 325. According to one or more embodiments, the EIC chip 320 may be mounted on the interposer substrate 200′ by a flip chip method. In one or more embodiments, an underfill material layer 800 provided on or surrounding the fourth bump 327 may be arranged between the EIC chip 320 and the interposer substrate 200′, but embodiments are not limited thereto. The underfill material layer 800 may be omitted.

The interposer substrate 200′ may include a wiring layer 230′ and a body layer 210′. The wiring layer 230′ may be located on the upper surface of body layer 210′. Through vias 215′ may be formed inside the body layer 210′. The through vias 215′ may pass through the body layer 210′ in the vertical direction Z. According to one or more embodiments, the through vias 215′ may include a TSV. The wiring layer 230′ may include wiring patterns 235′. The wiring patterns 235′ may electrically connect the first semiconductor chip 400, the second semiconductor chip 500, and the EIC chip 320 to each other, or form the electrical connection between the first semiconductor chip 400 and the through vias 215′, between the second semiconductor chip 500 and the through vias 215, and between the chip structure 300 and the through vias 215′. The through vias 215′ may be electrically connected to the package substrate 100 (see FIG. 2) through pads and bumps formed on the lower surface of the body layer 210.

Referring to FIG. 6, the interposer substrate 200′ may include the grating coupler 3135′. The grating coupler 3135′ may be located inside the interposer substrate 200′.

The vertical level of the upper surface of the grating coupler 3135′ may be lower than the vertical level of the lower surfaces of the first semiconductor chip 400 and the second semiconductor chip 500. For example, the grating coupler 3135′ may not overlap the first semiconductor chip 400 and the second semiconductor chip 500 in the horizontal direction (for example, X and/or Y direction). The grating coupler 3135′ may correspond to the grating coupler 3135 in FIG. 3.

The optical block 350 may be placed at a position that overlaps the grating coupler 3135′ in the vertical direction (Z direction) on the interposer substrate 200′. The optical block 350 may be spaced apart from the upper surface of the interposer substrate 200′ with the optical adhesive layer 335 between optical block 350 and the interposer substrate 200′. According to one or more embodiments, the optical adhesive layer 335 may be in direct contact with the optical block 350 and the interposer substrate 200′.

The optical block 350 may include a micro lens 330 that is convex in a direction toward the upper surface of the interposer substrate 200′. The distance d2 between the micro lens 330 and the upper surface of the interposer substrate 200′ may be 100 μm or less. As described above, a plurality of micro lenses 330 and a plurality of grating couplers 3135′ may be provided, wherein the plurality of micro lenses 330 may overlap the plurality of grating couplers 3135′, respectively, in the vertical direction (Z direction). This may prevent the light scattering and increase the coupling efficiency.

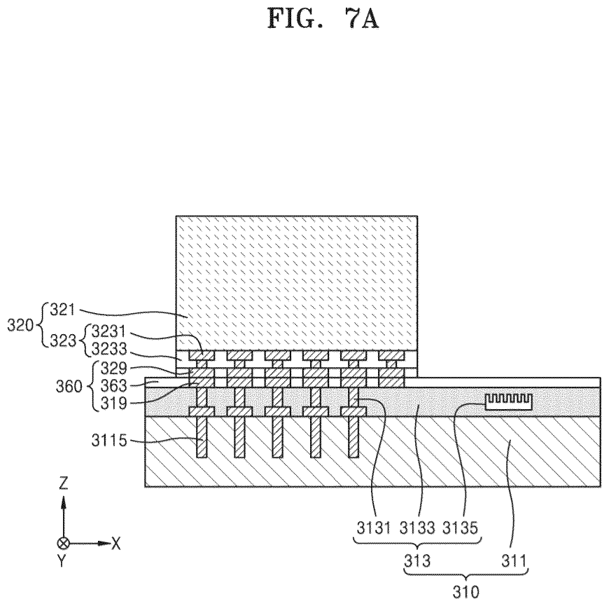

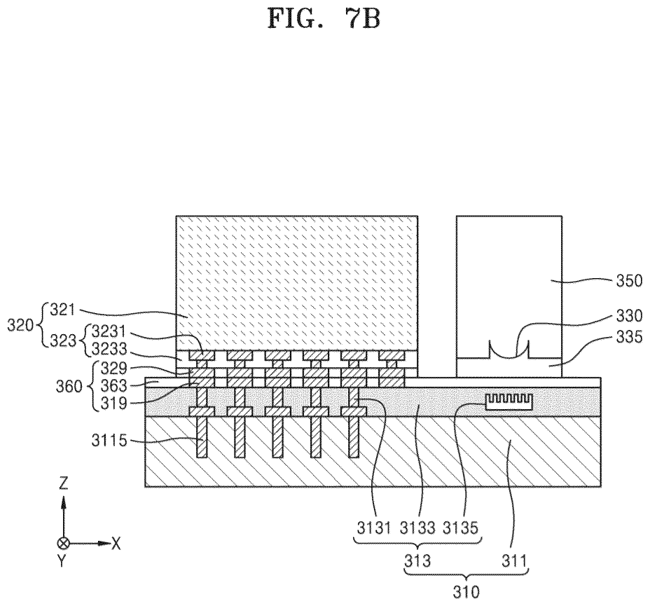

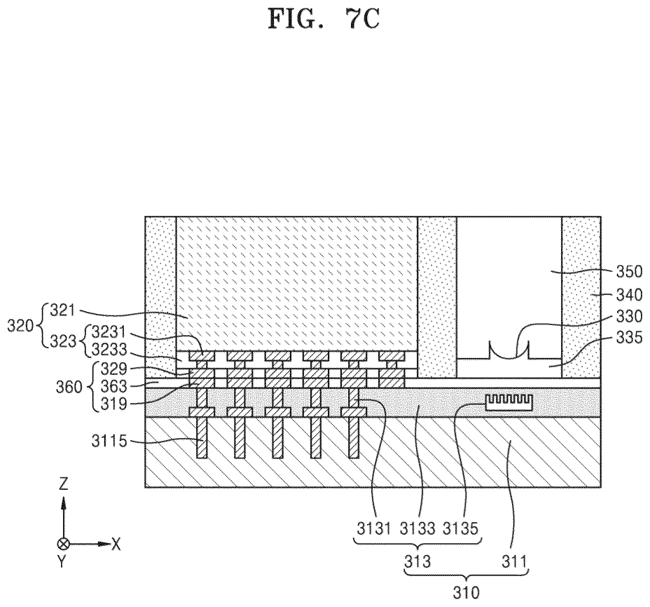

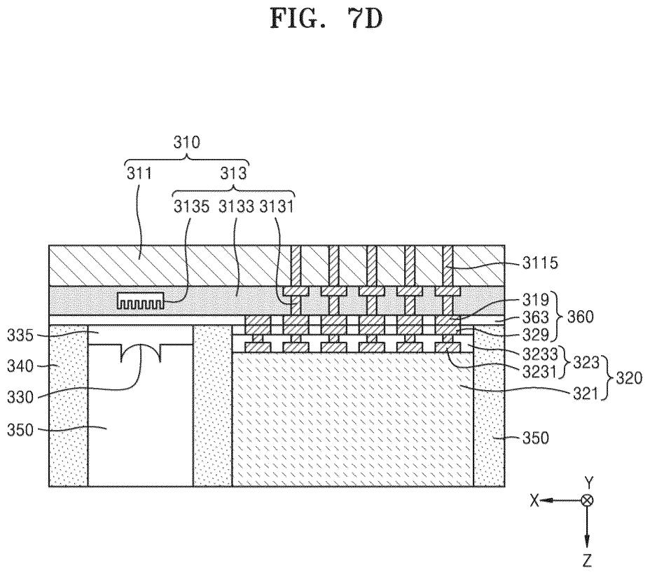

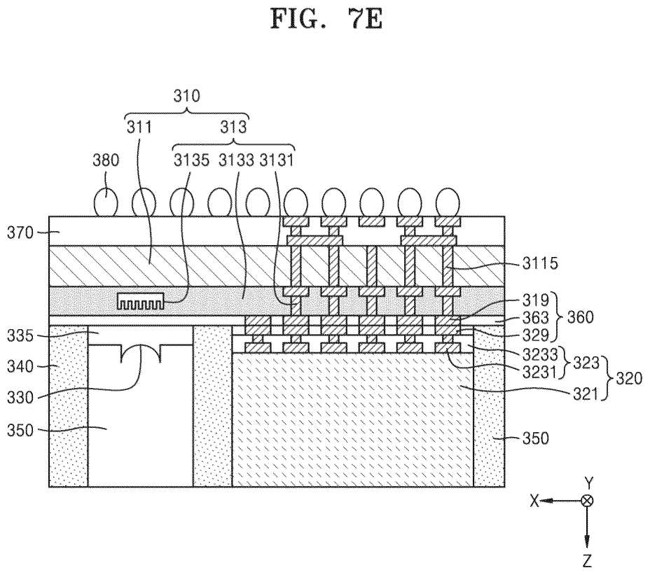

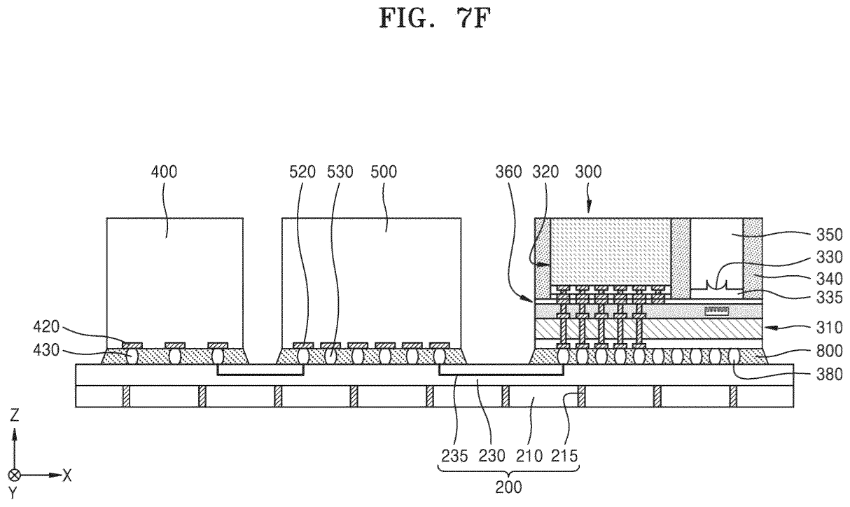

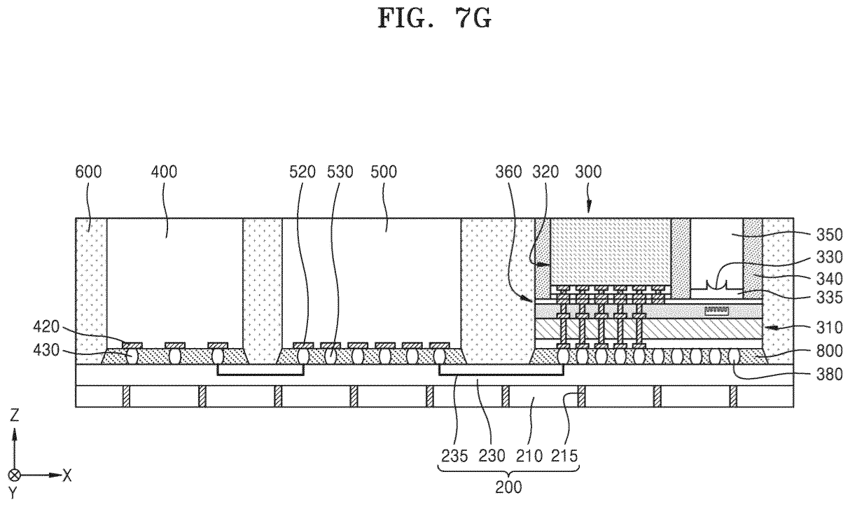

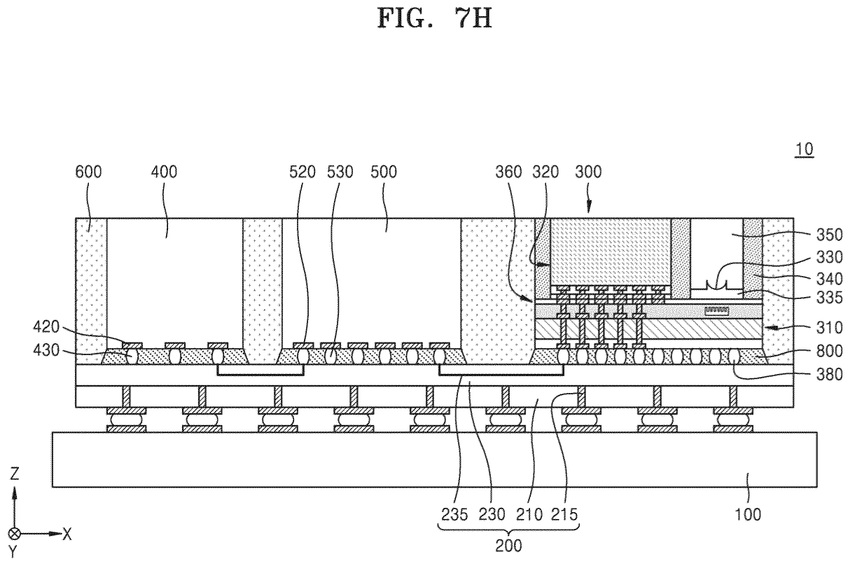

FIGS. 7A and 7H are cross-sectional views illustrating a manufacturing method of the semiconductor package of FIG. 2. Hereinafter, descriptions that are substantially the same as those given above with reference to FIGS. 1 to 5 may be omitted and differences are mainly described.

First, referring to FIG. 7A, a PIC chip 310 may be prepared and an EIC chip 320 may be attached on the PIC chip 310. The PIC chip 310 may include a first substrate 311 and a first wiring structure 313 located on the upper surface of the first substrate 311. Inside the first substrate 311, the through vias 3115 may be extended and connected to the first wiring structure 313. The EIC chip 320 may be attached on the PIC chip 310 in a face-down manner so that a second wiring structure 323 of the EIC chip 320 faces the first wiring structure 313 of the PIC chip 310.

In one or more embodiments, the PIC chip 310 and the EIC chip 320 may be bonded by hybrid bonding. The bonding layer 360 may be formed by hybrid bonding. The bonding layer 360 may be formed when the upper pads 319 of the PIC chip 310 are bonded with the lower pads 329 of the EIC chip 320 by hybrid bonding, and the first wiring insulating layer 3133 is bonded with the second wiring insulating layer 3233 by hybrid bonding. The PIC chip 310 and the EIC chip 320 may be electrically connected by the bonding layer 360.

Referring to FIGS. 7B and 7C, an optical block 350 is attached to the PIC chip 310. The optical adhesive layer 335 may be disposed on the lower surface of the optical block 350. The optical block 350 may include a downwardly convex micro lens 330 at the bottom. The micro lens 330 may improve the coupling efficiency of grating coupler 3135. Then, an insulating layer 340 is formed on the PIC chip 310. The insulating layer 340 may be formed on and to surround the EIC chip 320 and the optical block 350. After forming the insulating layer 340, the EIC chip 320, the optical block 350, and the insulating layer 340 may be formed to a desired thickness through a grinding or chemical-mechanical polishing (CMP) process. After the grinding or CMP process, the upper surface of the insulating layer 340 may be coplanar with the upper surface of each of the EIC chip 320 and the optical block 350.

Referring to FIGS. 7D and 7E, the chip structure of FIG. 7C is turned over (upside-down) and the first substrate 311 of the PIC chip 310 is ground so that the through vias 3115 are exposed from the first substrate 311. The process of grinding the first substrate 311 is a back grinding process, which may be a process of thinning the first substrate 311. When the through vias 3115 are exposed from the first substrate 311, a redistribution structure 370 is formed on the first substrate 311. The redistribution structure 370 may include a redistribution insulating layer and redistribution patterns, wherein the redistribution patterns may be connected to the exposed through vias 3115. Afterwards, first bumps 380 are formed on the redistribution structure 370.

Referring to FIGS. 7F to 7H, the first semiconductor chip 400, the second semiconductor chip 500, and the chip structure 300 of FIG. 7E are mounted on the interposer substrate 200. The chip structure 300 may be mounted on the interposer substrate 200 so that the first bumps 380 face the upper surface of the wiring layer 230 of the interposer substrate 200. The first semiconductor chip 400 and the second semiconductor chip 500 may be mounted together when the chip structure 300 is mounted on the interposer substrate 200. Afterwards, the molding member 600 is formed on the interposer substrate 200. The molding member 600 may cover each of the first semiconductor chip 400, the second semiconductor chip 500, and the chip structure 300. According to one or more embodiments, the upper surface of each of the first semiconductor chip 400, the second semiconductor chip 500, and the chip structure 300 may be exposed upward from the molding member 600 in the vertical direction Z. Then, the interposer substrate 200 is mounted on the package substrate 100.

While embodiments have been described with reference to the figures, it will be understood by those of ordinary skill in the art that various changes in form and details may be made therein without departing from the spirit and scope as defined by the following claims and their equivalents.

What is claimed is:

1. A chip structure, comprising:
a photonic integrated circuit chip comprising a grating coupler;
an electronic integrated circuit chip on the photonic integrated circuit chip;
an optical block on the photonic integrated circuit chip and spaced apart from the electronic integrated circuit chip in a horizontal direction, the optical block comprising a micro lens which is convex toward the photonic integrated circuit chip in a vertical direction; and an insulating layer surrounding the electronic integrated circuit chip and the optical block on the photonic integrated circuit chip,
wherein the micro lens overlaps the grating coupler in the vertical direction.

2. The chip structure of claim 1, wherein the micro lens comprises a plurality of micro lenses provided in the horizontal direction.

3. The chip structure of claim 1, wherein the micro lens is between the optical block and the photonic integrated circuit chip.

4. The chip structure of claim 1, further comprising:
a bonding layer between the electronic integrated circuit chip and the photonic integrated circuit chip; and
an optical adhesive layer between the optical block and the photonic integrated circuit chip.

5. The chip structure of claim 4, wherein the optical adhesive layer is in direct contact with the optical block and the bonding layer.

6. The chip structure of claim 4, wherein the micro lens overlaps at least one of the bonding layer and the electronic integrated circuit chip in the horizontal direction.

7. The chip structure of claim 6, wherein the photonic integrated circuit chip and the electronic integrated circuit chip are bonded to each other.

8. The chip structure of claim 1, wherein a distance between the micro lens and an upper surface of the photonic integrated circuit chip is less than or equal to 100 μm.

9. The chip structure of claim 1, wherein the optical block comprises at least one of glass, silicon, and polymer.

10. The chip structure of claim 1, wherein a thickness of the optical block is 600 μm to 800 μm in the vertical direction.

11. The chip structure of claim 1, wherein the grating coupler is spaced apart from the electronic integrated circuit chip in the vertical direction.

12. A semiconductor package, comprising:
an interposer substrate;
a first semiconductor chip, a second semiconductor chip, and an electronic integrated circuit chip on the interposer substrate, the first semiconductor chip, the second semiconductor chip, and the electronic integrated circuit chip being spaced apart from each other in a horizontal direction;
an optical block on the interposer substrate and spaced apart from the electronic integrated circuit chip in the horizontal direction, the optical block comprising a micro lens which is convex in a direction toward the interposer substrate;
an optical adhesive layer between the optical block and the interposer substrate; and
a molding member on the first semiconductor chip, the second semiconductor chip, the electronic integrated circuit chip, and the optical block,
wherein the interposer substrate is configured to electrically connect the electronic integrated circuit chip to the second semiconductor chip, the interposer substrate comprising a grating coupler that overlaps the micro lens in a vertical direction.

13. The semiconductor package of claim 12, wherein an upper surface of the molding member is coplanar with an upper surface of the first semiconductor chip, an upper surface of the second semiconductor chip, an upper surface of the electronic integrated circuit chip, and an upper surface of the optical block.

14. The semiconductor package of claim 12, wherein chip pads and bumps are between the electronic integrated circuit chip and the interposer substrate.

15. The semiconductor package of claim 12, wherein the grating coupler comprises a plurality of grating couplers and the micro lens comprises a plurality of micro lenses, and
one of the plurality of grating couplers that overlaps one of the plurality of micro lenses in the vertical direction and is spaced apart from another one of the plurality of micro lenses in the horizontal direction.

16. The semiconductor package of claim 12, wherein a thickness of the optical block is 600 μm to 800 μm in the vertical direction, and a distance between the micro lens and an upper surface of the interposer substrate is less than or equal to 100 μm in the vertical direction.

17. A semiconductor package, comprising:
a package substrate;
an interposer substrate on the package substrate;
a first semiconductor chip and a second semiconductor chip on the interposer substrate, the first semiconductor chip and the second semiconductor chip being spaced apart from each other in a horizontal direction;
an electronic integrated circuit chip on the interposer substrate and spaced apart from the first semiconductor chip and the second semiconductor chip in the horizontal direction;
an optical block spaced apart from the electronic integrated circuit chip in the horizontal direction, the optical block comprising a plurality of micro lenses at a bottom surface of the optical block and are convex toward the interposer substrate;
a plurality of grating couplers between the optical block and the package substrate, the plurality of grating couplers corresponding to the plurality of micro lenses, respectively; and
an optical adhesive layer between the plurality of grating couplers and the optical block,
wherein the plurality of grating couplers and the plurality of micro lenses are respectively provided in the horizontal direction.

18. The semiconductor package of claim 17, further comprising:
a photonic integrated circuit chip between the interposer substrate and the electronic integrated circuit chip, the photonic integrated circuit chip comprising the plurality of grating couplers; and
a bonding layer between the electronic integrated circuit chip and the photonic integrated circuit chip,
wherein the optical adhesive layer is in direct contact with the optical block and the bonding layer.

19. The semiconductor package of claim 17, wherein the plurality of grating couplers overlap the first semiconductor chip and the second semiconductor chip in the horizontal direction.

20. The semiconductor package of claim 17, wherein the plurality of grating couplers are inside the interposer substrate, and
a vertical level of an upper surface each of the plurality of grating couplers is less than a vertical level of a lower surface of the first semiconductor chip and a vertical level of a lower surface of the second semiconductor chip.
